(19) United States
(12) Patent Application Publication
(10) Pub. No.: US 2026/0190341 A1
(43) Pub. Date: Jul. 2, 2026

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Eunhyun KIM, Suwon-si (KR); Hyungjoon KIM, Suwon-si (KR); Mihye KANG, Suwon-si (KR); Woojin JANG, Suwon-si (KR)

(73) Assignee: Samsung Electronics Co., Ltd., Suwon-si (KR)

(21) Appl. No.: 19/243,799

(22) Filed: Jun. 20, 2025

(30) Foreign Application Priority Data
Dec. 26, 2024 (KR) 10-2024-0196460

(51) Int. Cl. H10B 43/35; H10B 41/10; H10B 41/27; H10B 41/35; H10B 41/41; H10B 43/10; H10B 43/27; H10B 43/40

(52) U.S. Cl. CPC H10B 43/35; H10B 41/10; H10B 41/27; H10B 41/35; H10B 41/41; H10B 43/10; H10B 43/27; H10B 43/40

(57) ABSTRACT

A semiconductor device includes a first semiconductor structure including a substrate, circuit elements, and circuit interconnection lines; and a second semiconductor structure. The second semiconductor structure includes a plate layer; first and second stack structures including gate electrodes and interlayer insulating layers alternately stacked, the gate electrodes including a lower gate electrode, memory gate electrodes, and an upper gate electrode; and a channel structure including a plurality of channel portions. The channel structure includes a filling insulating layer; a channel layer on a side surface of the filling insulating layer; a channel dielectric layer including a tunneling layer, a charge storage layer, and a blocking layer. The blocking layer includes a first and second regions, and a first thickness of an upper portion of the blocking layer in the first region is greater than a second thickness of a lower portion of the blocking layer in the second region.

### CROSS-REFERENCE TO RELATED APPLICATION(S)

This application claims benefit of priority to Korean Patent Application No. 10-2024-0196460 filed on Dec. 26, 2024, in the Korean Intellectual Property Office, the disclosure of which is incorporated herein by reference in its entirety.

### BACKGROUND

Some example embodiments of the present disclosure relate to semiconductor devices and data storage systems including the same.

Semiconductor devices capable of storing high-capacity data in data storage systems requiring data storage have become desirable. Accordingly, methods for increasing data storage capacity of semiconductor devices have been researched. For example, as a method for increasing integration density of a semiconductor device, a semiconductor device including memory cells and a peripheral circuit region disposed vertically has been suggested.

### SUMMARY

Some example embodiments of the present disclosure provide a semiconductor device having improved reliability, and a data storage system including the same.

Some example embodiments of the present disclosure provide a semiconductor device that includes a first semiconductor structure including a substrate, circuit elements on the substrate, and circuit interconnection lines on the circuit elements; and a second semiconductor structure on the first semiconductor structure. The second semiconductor structure includes a plate layer; a first stack structure and a second stack structure stacked in a first direction perpendicular to an upper surface of the plate layer, the first stack structure being on the upper surface of the plate layer, the first stack structure and the second stack structure including gate electrodes and interlayer insulating layers alternately stacked on each other in the first direction, the first stack structure including a first lower gate electrode, first memory gate electrodes, and a first upper gate electrode sequentially stacked, and the second stack structure including a second lower gate electrode, second memory gate electrodes, and a second upper gate electrode sequentially stacked; and a channel structure including a plurality of channel portions penetrating the first stack structure and the second stack structure, respectively, the plurality of channel portions being connected to each other in the first direction. The channel structure includes a filling insulating layer extending in the first direction within the plurality of channel portions; a channel layer on a side surface of the filling insulating layer opposing the gate electrodes and the interlayer insulating layers; and a channel dielectric layer including a tunneling layer, a charge storage layer, and a blocking layer, in order between the channel layer and the gate electrodes. The blocking layer includes a first region penetrating the first stack structure and a second region penetrating the second stack structure, and a first thickness of an upper portion of the blocking layer on a side surface of the charge storage layer in the first region is greater than a second thickness of a lower portion of the blocking layer on a side surface of the charge storage layer in the second region.

Some example embodiments of the present disclosure further provide a semiconductor device that includes a plate layer; a plurality of stack structures including gate electrodes and interlayer insulating layers alternately stacked in a first direction on the plate layer; and a channel structure including a plurality of channel portions penetrating the plurality of stack structures, respectively, the plurality of channel portions being connected to each other in the first direction. The channel structure includes a filling insulating layer extending in the first direction within the plurality of channel portions; a channel layer on a side surface of the filling insulating layer opposing the gate electrodes and the interlayer insulating layers; and a channel dielectric layer including a tunneling layer, a charge storage layer, and a blocking layer in order between the channel layer and the gate electrodes. In a channel portion of the plurality of channel portions on a lowermost end of the channel structure, the blocking layer includes a bent portion having a thickness that changes discontinuously between a vertical region in an extension direction of the channel portion on the lowermost end of the channel structure and a horizontal region extending in a second direction perpendicular to the first direction. A thickness of the vertical region is greater than a thickness of the horizontal region.

Some example embodiments of the present disclosure still further provide a data storage system that includes a semiconductor storage device including a first semiconductor structure, a second semiconductor structure on a surface of the first semiconductor structure, and an input/output pad electrically connected to circuit elements of the first semiconductor structure; and a controller electrically connected to the semiconductor storage device through the input/output pad, the controller controlling the semiconductor storage device. The second semiconductor structure includes a plate layer; a first stack structure and a second stack structure stacked in a first direction perpendicular to an upper surface of the plate layer, the first stack structure being on the upper surface of the plate layer, the first stack structure and the second stack structure including gate electrodes and interlayer insulating layers alternately stacked on each other in the first direction, the first stack structure including a first lower gate electrode, first memory gate electrodes, and a first upper gate electrode sequentially stacked, and the second stack structure including a second lower gate electrode, second memory gate electrodes, and a second upper gate electrode sequentially stacked; and a channel structure including a plurality of channel portions penetrating the first stack structure and the second stack structure, respectively, the plurality of channel portions being connected to each other in the first direction. The channel structure includes a filling insulating layer extending in the first direction within the plurality of channel portions; a channel layer on a side surface of the filling insulating layer opposing the gate electrodes and the interlayer insulating layers; and a channel dielectric layer including a tunneling layer, a charge storage layer, and a blocking layer, in order between the channel layer and the gate electrodes. The blocking layer includes a first region penetrating the first stack structure and a second region penetrating the second stack structure, and a first thickness of an upper portion of the blocking layer on a side surface of the charge storage layer in the first region is greater than a second thickness of a lower portion of the blocking layer on a side surface of the charge storage layer in the second region.

Some example embodiments of the present disclosure provide a method of manufacturing a semiconductor device including forming a peripheral region circuit including circuit elements, a circuit interconnection structure and a peripheral region insulating layer on a substrate; forming a plate layer, a horizontal sacrificial layer and a horizontal conductive layer on the peripheral region circuit; forming a first molded structure by alternately stacking sacrificial insulating layers and interlayer insulating layers on the horizontal conductive layer; forming first channel holes in a vertical direction of an upper surface of the substrate so as to penetrate the first molded structure; forming a first blocking layer on an inner side surface of the first channel holes formed to penetrate the first molded structure; forming first vertical sacrificial layers in the first channel holes; forming a second molded structure by alternately stacking sacrificial insulating layers and interlayer insulating layers on the first molded structure; forming second channel holes in the vertical direction to penetrate the second molded structure; forming second vertical sacrificial layers in the second channel holes; forming third molded structures by alternately stacking sacrificial insulating layers and interlayer insulating layers on the second molded structure; forming third channel holes in the vertical direction to penetrate the third molded structure; forming third vertical sacrificial layers in the third channel holes; forming channel holes penetrating the first to third molded structure by removing the first to third vertical sacrificial layers using an ashing process using oxygen; and depositing at least a portion of a channel dielectric layer, a channel layer, and a channel filled insulating layer in order within the channel holes, and forming a channel pad.

Some example embodiments of the present disclosure still further provide a method of manufacturing a semiconductor device that includes forming a first molded structure in a memory cell region on a peripheral circuit region, the first molded structure including a plate layer, and first sacrificial insulating layers and first interlayer insulating layers alternately stacked on the plate layer; forming a first channel hole penetrating the first molded structure and the plate layer; forming a first blocking layer on an inner side surface of the first channel hole; forming a first vertical sacrificial layer on the first blocking layer in the first channel hole; forming a second molded structure on the first molded structure by alternately stacking second sacrificial insulating layers and second interlayer insulating layers on the first molded structure; forming a second channel hole penetrating the second molded structure, the second channel hole being over the first channel hole and exposing the first vertical sacrificial layer; forming a second vertical sacrificial layer in the second channel hole; forming a third molded structure on the second molded structure by alternately stacking third sacrificial insulating layers and third interlayer insulating layers on the second molded structure; forming a third channel hole penetrating the third molded structure, the third channel hole being over the second channel hole and exposing the second vertical sacrificial layer; forming a third vertical sacrificial layer in the third channel hole; removing the first vertical sacrificial layer, the second vertical sacrificial layer and the third vertical sacrificial layer; removing the first sacrificial insulating layers, the second sacrificial insulating layers and the third sacrificial insulating layers, after the removing of the first vertical sacrificial layer, the second vertical sacrificial layer and the third vertical sacrificial layer; forming gate electrodes between the first interlayer insulating layers, the second interlayer insulating layers and the third interlayer insulating layers, after the removing of the first sacrificial insulating layers, the second sacrificial insulating layers and the third sacrificial insulating layers; forming a channel structure in the first channel hole, the second channel hole and the third channel hole; and depositing a channel pad on a top surface of the channel structure.

In some example embodiments of the method of manufacturing the semiconductor device, the removing of the first vertical sacrificial layer, the second vertical sacrificial layer and the third vertical sacrificial layer includes an ashing process.

In some example embodiments of the method of manufacturing the semiconductor device, the forming of the channel structure includes depositing a channel dielectric layer, a channel layer and a channel filled insulating layer in order in the first channel hole, the second channel hole and the third channel hole.

In some example embodiments of the method of manufacturing the semiconductor device, a center of the first channel hole along a horizontal direction, a center of the second channel hole along the horizontal direction, and a center of the third channel hole along the horizontal direction are vertically aligned with each other.

In some example embodiments of the method of manufacturing the semiconductor device, a center of the first channel hole along a horizontal direction, a center of the second channel hole along the horizontal direction, and a center of the third channel hole along the horizontal direction are vertically misaligned with respect to each other.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to some example embodiments of the present disclosure;

FIG. 2 is a cross-sectional diagram illustrating a semiconductor device according to some example embodiments of the present disclosure, taken along line I-I′ in FIG. 1;

FIG. 3 is an enlarged diagram illustrating a semiconductor device according to some example embodiments of the present disclosure, illustrating region ‘A’ in FIG. 2;

FIG. 4 is an enlarged diagram illustrating a portion of a semiconductor device according to some example embodiments of the present disclosure, illustrating region ‘B’ in FIG. 2;

FIG. 5 is an enlarged diagram illustrating a portion of a semiconductor device according to some example embodiments of the present disclosure, illustrating a region corresponding to FIG. 4;

FIG. 6 is an enlarged diagram illustrating a portion of a semiconductor device according to some example embodiments of the present disclosure, illustrating a region corresponding to FIG. 4;

FIG. 7 is an enlarged diagram illustrating a portion of a semiconductor device according to some example embodiments of the present disclosure, illustrating a region corresponding to FIG. 4;

FIG. 8A is a cross-sectional diagram illustrating a semiconductor device according to some example embodiments of the present disclosure, illustrating a region corresponding to FIG. 2;

FIG. 8B is a cross-sectional diagram illustrating a semiconductor device according to some example embodiments of the present disclosure, illustrating region ‘C’ in FIG. 8A;

FIGS. 9A, 9B, 9C, 9D, 9E, 9F, 9G, 9H, 9I, 9J and 9K are cross-sectional diagrams illustrating a method of manufacturing a semiconductor device according to some example embodiments of the present disclosure, illustrating regions corresponding to FIG. 2;

FIG. 10 is a diagram illustrating a data storage system including a semiconductor device according to some example embodiments of the present disclosure; and

FIG. 11 is a perspective diagram illustrating a data storage system including a semiconductor device according to some example embodiments of the present disclosure.

### DETAILED DESCRIPTION

Hereinafter, some example embodiments of the present disclosure will be described as follows with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

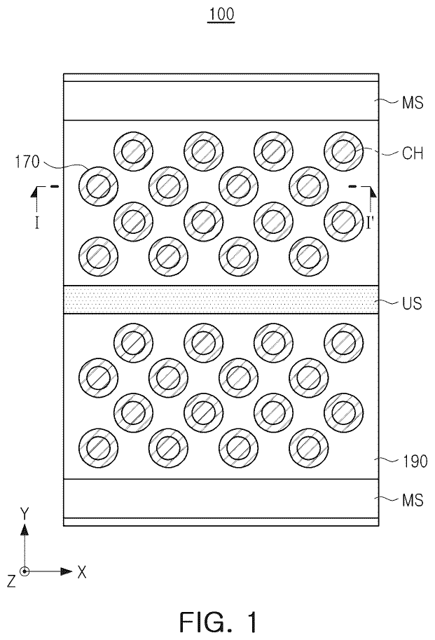

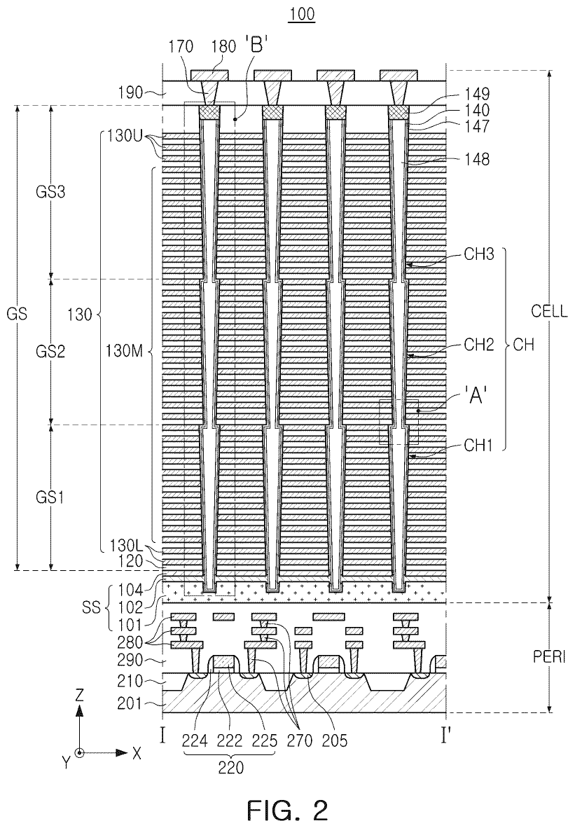

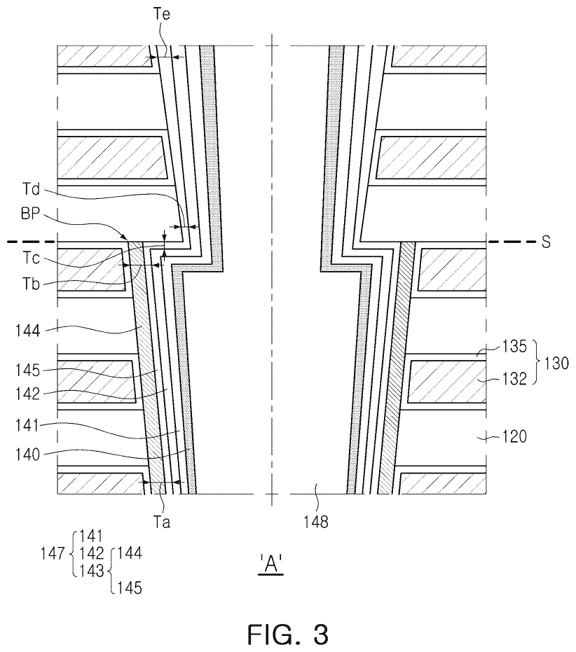

FIG. 1 is a plan diagram illustrating a semiconductor device according to some example embodiments. FIG. 2 is a cross-sectional diagram illustrating a semiconductor device according to some example embodiments, taken along line I-I′ in FIG. 1. FIG. 3 is an enlarged diagram illustrating a semiconductor device according to some example embodiments, illustrating region ‘A’ in FIG. 2.

Referring to FIGS. 1 to 3, a semiconductor device 100 may include a peripheral circuit region PERI, which is a first semiconductor structure including a substrate 201, and a memory cell region CELL, which is a second semiconductor structure including a plate layer 101. The memory cell region CELL may be disposed on the peripheral circuit region PERI. In some example embodiments, alternately, the memory cell region CELL may be disposed below the peripheral circuit region PERI.

The peripheral circuit region PERI may include a substrate 201, impurity regions 205 and device isolation layers 210 within the substrate 201, circuit elements 220 disposed on the substrate 201, a peripheral region insulating layer 290, circuit contact plugs 270, and circuit interconnection lines 280.

The substrate 201 may have an upper surface extending in the X-direction and the Y-direction. The substrate 201 may have an active region defined by the device isolation layers 210. The impurity regions 205 including impurities may be disposed in a portion of the active region. The substrate 201 may include a semiconductor material, such as a group IV semiconductor, a group III-V compound semiconductor, or a group II-VI semiconductor. The substrate 201 may be provided as a bulk wafer or an epitaxial layer.

The circuit elements 220 may include a planar transistor. Each of the circuit elements 220 may include a circuit channel dielectric layer 222, a spacer layer 224, and a circuit gate electrode 225. The impurity regions 205 may be disposed in the substrate 201 on both sides of the circuit gate electrode 225 as source/drain regions.

A peripheral region insulating layer 290 may be disposed on the circuit device 220 on the substrate 201. The peripheral region insulating layer 290 may include a plurality of insulating layers formed by different processes. The peripheral region insulating layer 290 may be formed of an insulating material.

Circuit contact plugs 270 and circuit interconnection lines 280 may be included in a circuit interconnection structure electrically connected to the circuit elements 220 and the impurity regions 205. The circuit contact plugs 270 may have a cylindrical shape, and the circuit interconnection lines 280 may have a line shape. An electrical signal may be applied to the circuit device 220 by the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270 and may be disposed in a plurality of layers. The circuit contact plugs 270 and the circuit interconnection lines 280 may include a conductive material, for example, tungsten (W), copper (Cu), aluminum (Al), or the like, and each component may further include a diffusion barrier. In some example embodiments, the number of layers of the circuit contact plugs 270 and the circuit interconnection lines 280 may be varied.

The memory cell region CELL may include a source structure SS, gate electrodes 130 stacked on the source structure SS, interlayer insulating layers 120 alternately stacked with the gate electrodes 130 and included in the stack structure GS, channel structures CH disposed to penetrate the gate electrodes 130, first isolation regions MS extending while penetrating the gate electrodes 130, cell region insulating layers 190 on the channel structures CH, studs 170 connected to the channel structures CH, respectively, a second isolation region US penetrating the upper gate electrodes 130U among the gate electrodes 130 between the studs 170, and bitlines 180 on the studs 170.

The source structure SS may include a plate layer 101, a first horizontal conductive layer 102, and a second horizontal conductive layer 104 stacked in order. However, in some example embodiments, the number of conductive layers included in the source structure SS may be varied.

The plate layer 101 may have a plate shape and may function as at least a portion of a common source line of the semiconductor device 100. The plate layer 101 may have an upper surface extending in the X-direction and the Y-direction. The plate layer 101 may include a conductive material. For example, the plate layer 101 may include a semiconductor material, such as a group IV semiconductor, a group III-V compound semiconductor, or a group II-VI semiconductor. For example, the group IV semiconductor may include silicon, germanium, or silicon-germanium. The plate layer 101 may further include impurities. The plate layer 101 may be provided as a polycrystalline semiconductor layer, such as a polycrystalline silicon layer, or an epitaxial layer.

The first and second horizontal conductive layers 102 and 104 may be stacked in order on an upper surface of the plate layer 101. The first horizontal conductive layer 102 may function as a portion of a common source line of the semiconductor device 100, for example, may function as a common source line together with the plate layer 101. As illustrated in FIG. 2, the first horizontal conductive layer 102 may be directly connected to the channel layer 140 at the periphery of the channel layer 140.

The first and second horizontal conductive layers 102 and 104 may include a semiconductor material, for example, may include polycrystalline silicon. In some example embodiments, at least the first horizontal conductive layer 102 may be doped with impurities having the same conductivity-type as that of the plate layer 101, and the second horizontal conductive layer 104 may be a doped layer or a layer including impurities diffused from the first horizontal conductive layer 102.

Gate electrodes 130 may be vertically spaced apart from each other and stacked on the upper surface of the plate layer 101, and may be included in a stack structure (GS: GS1-GSk) together with the interlayer insulating layers 120. The stack structure GS may include a plurality of stages of stack structures GS1-GSk vertically stacked. In FIG. 2, first to third stack structures GS1, GS2, and GS3 may be included, but some example embodiments thereof are not limited thereto, and stack structures GS1-GS4, GS1-GS6 having 4 stages to 6 stages may be included. In some example embodiments, the stack structure GS1-GSk may include stack structures GS1-GS2 having 2 stages.

Each stage of the stack structure GS1-GSk may be classified by a height of the stack structure on which a channel hole process in a desired (and/or alternatively predetermined) depth of the channel structure CH, and may be distinguished by each of the channel portions of the channel structure CH.

The lower stack structure located on an upper surface of the plate layer 101 may be denoted as the first stack structure GS1, and the stack structures GS2-GSk on the first stack structure GS1 may be denoted in order as the second stack structure GS2, the third stack structure GS3, the fourth stack structure GS4 to the kth stack structure GSk (k=5), respectively, and the second to third stack structures GS2-GS3 may be denoted as the upper stack structure. Also, the kth stack structure GSk (k=3) disposed in the uppermost portion and disposed farthest from the plate layer 101 in the Z-direction may be denoted as an uppermost stack structure.

In the stack structures GS1-GSk, the gate electrodes 130 and the interlayer insulating layers 120 may be alternately stacked in the Z-direction, and a boundary surface S between the stack structures GS1-GSk may be defined as an interfacial surface between the stack structures GS1-GSk. For example, the boundary surface S may be defined as an interfacial surface between the uppermost gate electrode 130 of the lower stack structure and the lowermost interlayer insulating layer 120 of the upper stack structure, but some example embodiments thereof are not limited thereto. A thickness of the lowermost interlayer insulating layer 120 and the uppermost gate electrode 130 disposed in the boundary surface S may be the same or substantially the same as a thickness of other interlayer insulating layers 120 and the gate electrode 130, but some example embodiments thereof are not limited thereto. A length in the Z-direction and the number of the gate electrodes 130 of each of the stack structures GS1-GS3 may be the same or substantially the same, but some example embodiments thereof are not limited thereto.

The gate electrodes 130 may be vertically spaced apart from each other on the plate layer 101 and may be included in the stack structure GS together with interlayer insulating layers 120. The stack structure GS may include lower and upper stack structures vertically stacked. However, according to some example embodiments, the stack structure GS may be formed as a single stack structure.

The gate electrodes 130 may include lower gate electrodes 130L included in gates of ground select transistors, memory gate electrodes 130M included in a plurality of memory cells, and upper gate electrodes 130U included in gates of string select transistors. The number of the memory gate electrodes 130M included in memory cells may be determined depending on capacity of the semiconductor device 100. The upper gate electrode 130U and the lower gate electrode 130L may also be referred to as an upper select gate electrode and a lower select gate electrode, respectively. according to some example embodiments, the upper and lower gate electrodes 130U and 130L may be 1 to 4 or more, respectively, and may have a structure the same as or different from the memory gate electrodes 130M. In some example embodiments, the gate electrodes 130 may further include a gate electrode disposed on one side of the upper gate electrodes 130U and/or the lower gate electrode 130L and included in an erase transistor used for an erase operation using a gate induced drain leakage (GIDL) phenomenon. Also, a portion of the gate electrodes 130, for example, the memory gate electrodes 130M adjacent to the upper or lower gate electrodes 130U and 130L, may be dummy gate electrodes.

The gate electrodes 130 may include the same material. The gate electrodes 130 may include a first conductive layer 132 and a second conductive layer 135 as illustrated in FIGS. 3 to 7. The second conductive layer 135 may surround an upper surface, a lower surface, and a side surface of the first conductive layer 132. The channel structures CH may be in contact with the second conductive layers 135. The gate electrodes 130 include the second conductive layer 135 that may cover side surfaces of the first conductive layers 132 in regions in contact with the channel structures CH.

The interlayer insulating layers 120 may be disposed alternately with the gate electrodes 130. Similarly to the gate electrodes 130, the interlayer insulating layers 120 may be spaced apart from each other in a direction, perpendicular to an upper surface of the plate layer 101. A portion of the interlayer insulating layers 120 may have different thicknesses. For example, the interlayer insulating layer 120 disposed adjacent to the region in which the first channel structure CH1 and the second channel structure CH2 are connected to each other and the interlayer insulating layer 120 on the upper gate electrode 130U in an uppermost portion may have a relatively great thickness, but some example embodiments thereof are not limited thereto. The interlayer insulating layers 120 may include an insulating material such as silicon oxide or silicon nitride.

The channel structures CH may penetrate the stack structure GS, may extend in the Z-direction and may be connected to the plate layer 101. Each of the channel structures CH may form a memory cell string and may be spaced apart from each other while forming rows and columns on the plate layer 101. As illustrated in FIG. 1, the channel structures CH may be disposed to form a grid pattern on the x-y plane or may be disposed in a zigzag pattern in one direction. The channel structures CH may have a columnar shape and may have an inclined side surface of which a width may decrease toward the plate layer 101 depending on an aspect ratio.

In each of the channel structures CH, k number of the channel portions CH1-CHk (k is 1, 2, 3, 4, that is, a positive integer) penetrating k number of the stack structures GS1-GSk of the gate electrodes 130, respectively, may be connected to each other, and in some example embodiments, first to third channel portions CH1-CH3 penetrating three stack structures GS1-GS3 may be connected to each other. The first to third channel portions CH1-CH3 may have a form aligned along the same central line, and accordingly, a center of a width of an upper surface of each of the first to third channel portions CH1-CH3 may be positioned on a linear line.

Each of the channel structures CH may include a channel layer 140 disposed in a channel hole, a channel dielectric layer 147, a channel filled insulating layer 148 (e.g., a channel filling insulating layer), and a channel pad 149 as illustrated in FIGS. 2 and 3. The channel layer 140 may be formed in an annular shape surrounding the channel filled insulating layer 148 therein, but according to some example embodiments, the channel layer 140 may have a columnar shape such as a cylindrical shape or a prism shape without the channel filled insulating layer 148. The channel layer 140 may be connected to the first horizontal conductive layer 102 in a lower portion. The channel layer 140 may include a semiconductor material such as polycrystalline silicon or single crystal silicon.

The channel dielectric layer 147 may be disposed between the gate electrodes 130 and the channel layer 140. The channel dielectric layer 147 may include a tunneling layer 141, a charge storage layer 142, and a blocking layer 143 stacked in order from the channel layer 140. The channel layer 140, the channel dielectric layer 147, and the filled insulating layer 148 may be connected to each other between the first to third channel portions CH1-CH3.

The tunneling layer 141 may tunnel electric charges into the charge storage layer 142, and may include, for example, silicon oxide (SiO₂), silicon nitride (Si₃N₄), silicon oxynitride (SiON), or a combination thereof. The charge storage layer 142 may be a charge trap layer or a floating gate conductive layer. The blocking layer 143 may include first to second blocking layers 144 and 145.

The channel pad 149 may be disposed only on an upper end of the channel structures CH. Differently from the illustrated example, the channel pad 149 may be disposed to fill the channel layer 140 on an upper end. The channel pad 149 may include, for example, doped polycrystalline silicon.

The first isolation regions MS may be disposed to penetrate the stack structure GS and may extend in the X-direction. Although not illustrated, the first isolation regions MS may be disposed parallel to each other. Although not illustrated in the drawing, the first isolation regions MS may penetrate the stack structure GS, may further penetrate the first and second horizontal conductive layers 102 and 104 therebelow, and may be connected to the plate layer 101. The first isolation regions MS may have a shape of which a width decreases toward the plate layer 101 due to a high aspect ratio. The first isolation regions MS may include an insulating material, for example, silicon oxide, silicon nitride, or silicon oxynitride.

The cell region insulating layer 190 may be disposed on the stack structure GS. The cell region insulating layer 190 may cover upper surfaces of the channel structures CH. The cell region insulating layer 190 may include an insulating material, and may include a plurality of insulating layers.

Studs 170 may be physically and electrically connected to the channel structures CH on the channel structures CH, respectively. The studs 170 may penetrate the cell region insulating layer 190 and may be connected to the channel pads 149 of the channel structures CH. The studs 170 may electrically connect the channel structures CH to the bitlines 180.

The studs 170 may have a cylindrical shape and may have an inclined side surface of which a width may decrease toward the channel structures CH. The studs 170 may include a conductive material, such as tungsten (W), aluminum (Al), ruthenium (Ru), molybdenum (Mo), copper (Cu), or the like. according to some example embodiments, the studs 170 may include the same material as that of the gate electrodes 130 or may include a material different from that of the gate electrodes 130. When the studs 170 include the same material as the gate electrodes 130, the studs 170 may be formed by forming sacrificial layers and replacing the sacrificial layers.

The second isolation region US may extend in the X-direction between the adjacent first isolation regions MS as illustrated in FIG. 1, and may penetrate the upper gate electrodes 130U among the gate electrodes 130. The second isolation region US may be disposed between the studs 170. The two isolation regions US may include an insulating material, for example, silicon oxide, silicon nitride, or silicon oxynitride.

The bit lines 180 form a cell interconnection structure electrically connected to memory cells in the memory cell region CELL. The bitlines 180 may be electrically connected to the channel structures CH through the studs 170. The bitlines 180 may be disposed to extend in the Y-direction, for example. The bitlines 180 may include a conductive material, for example, a metal, such as tungsten (W), copper (Cu), aluminum (Al), or the like.

As the number of stacks increases, an aspect ratio of the channel structure may increase. Accordingly, a depth of the channel hole may increase. As the depth of the channel hole increases, the step coverage may decrease during deposition of the channel dielectric layer, which may cause reduction of the thickness of the channel dielectric layer toward the plate layer 101. As the thickness of the channel dielectric layer decreases toward the plate layer, a thickness of an upper end of the channel dielectric layer may be greater than the thickness of the lower end in one channel portion, and the thickness of the upper end may be greater than the thickness of the lower end in the entire channel portion. As the upper end thickness and the lower end thickness of the channel dielectric layer are different, an operation speed of the cell may be different on a lower end and an upper end, and reliability issues may occur.

In some example embodiments, a semiconductor device 100 may further deposit a blocking layer on the first channel portion CH1 of the first stack structure GS1, which is the lowermost end stack structure, and the thickness of the blocking layer 143 in the first stack structure GS1 may increase, such that a difference in thicknesses of the blocking layers 143 in the first stack structure GS1 and the second stack structure GS2 may be reduced, and reliability with respect to operation speed of the cell between the lower end and the upper end may be improved.

Referring to FIGS. 2 and 3, the blocking layer 143 in the first stack structure GS1, which is the lower stack structure, may include the first blocking layer 144 and the second blocking layer 145, and the blocking layer 143 in the second to third stack structures GS2-GS3, which are the upper stack structures, may include the second blocking layer 145.

The blocking layer 143 may have a first region penetrating the first stack structure GS1, a second region penetrating the second stack structure GS2, and a third region penetrating the third stack structure GS3. The thickness of an upper portion of the blocking layer 143 on the side surface of the charge storage layer in the first region may be greater than the thickness of a lower portion of the blocking layer on the side surface of the charge storage layer in the second region.

In the first region, the upper surface of the first blocking layer 144 partially in contact with the second stack structures GS2, and the upper surface of the second blocking layer 145 partially in contact with the second stack structures GS2 may be coplanar with each other.

The first blocking layer 144 may refer to a blocking layer deposited before filling the channel hole with a sacrificial film after the first stack structure GS1 is formed. The first blocking layer 144 may not extend to the second channel portion and third channel portions CH2-CH3, and may be disposed on the side surface of the channel hole of the first channel portion CH1. The first blocking layer 144 may include silicon oxide (SiO₂), a high-κ dielectric material, or a combination thereof. The thickness of the first blocking layer 144 may range from about 1 nm to about 5 nm.

The second blocking layer 145 may refer to a blocking layer deposited after the first blocking layer 144 is formed. The second blocking layer 145 may be disposed on the side surface of the channel hole of the first to third channel portions CH1-CH3. The second blocking layer 145 may include silicon oxide (SiO₂), a high-κ dielectric material, or a combination thereof.

Referring to FIGS. 2 and 3, in the first channel portion CH1, a tunneling layer 141, a charge storage layer 142, a second blocking layer 145, and a first blocking layer 144 may be disposed in order between the channel layer 140 and the gate electrodes 130, and in the second to third channel portion CH2-CH3, a tunneling layer 141, a charge storage layer 142, and a second blocking layer 145 may be disposed in order between the channel layer 140 and the gate electrodes 130.

In the first region, the blocking layer 143 may include the first blocking layer 144 and the second blocking layer 145 including different materials, and when the same material is included, a boundary between the layers may not be distinct. Accordingly, the first blocking layer 144 and the second blocking layer 145 may be recognized as a single blocking layer 143 without distinction. However, in FIG. 3, the first blocking layer 144 and the second blocking layer 145 may be distinct from each other for ease of description.

In the process of depositing the channel dielectric layer in the channel hole having a large aspect ratio, the step coverage may decrease, and accordingly, referring to FIG. 3, it may be confirmed that the thickness of the channel dielectric layer 147 including the blocking layer 143 may decrease toward the plate layer 101. Accordingly, it may be confirmed that the thickness of the channel dielectric layer 147 including the blocking layer 143 in each channel portion may decrease toward the plate layer 101. For example, the thickness of the blocking layer 143 in the first and third regions may decrease toward the plate layer 101.

The thickness of the blocking layer 143 in the first channel portion CH1 may decrease toward the plate layer 101. For example, the upper thickness Tb of the blocking layer 143 in the first channel portion CH1 may be greater than the lower thickness Ta of the blocking layer 143 in the first channel portion CH1. Since the blocking layer 143 in the first channel portion CH1 includes the first blocking layer 144 and the second blocking layer 145, the thickness of the blocking layer 143 in the first channel portion CH1 may indicate a thickness which is the sum of the thickness of the first blocking layer 144 and the thickness of the second blocking layer 145 in the first channel portion CH1. The blocking layer 143 in the first channel portion CH1 may have a thickness in a range of about 5 nm to about 10 nm.

The thickness of the blocking layer 143 in the second channel portion CH2 may decrease toward the plate layer 101. For example, the upper thickness Te of the blocking layer 143 in the second channel portion CH2 may be greater than the lower thickness Td of the blocking layer 143 in the second channel portion CH2. The blocking layer 143 in the second channel portion CH2 may have a thickness in a range of about 4 nm to about 8 nm.

The blocking layer 143 may include a bent portion BP of which a thickness discontinuously changes on a boundary surface S between the first stack structure GS1 and the second stack structure GS2. Since the blocking layer 143 further includes the first blocking layer 144 in the first channel portion CH1, the bent portion BP of which a thickness discontinuously changes on the boundary surface S may be included.

For example, the blocking layer 143 may include a bent portion BP of which a thickness discontinuously changes between a vertical region in the extension direction of the first channel portion CH1 and a horizontal region extending in a direction, perpendicular to the z-axis direction.

The thickness Ta and Tb of the vertical region of the blocking layer 143 in the first channel portion CH1 may be greater than the thickness Tc of the horizontal region. Referring to FIG. 3, it may be confirmed that the thickness Ta and Tb of the vertical region of the blocking layer 143 in the first channel portion CH1 may be the sum of the side surface thickness of the first blocking layer 144 and the side surface thickness of the second blocking layer 145. Also, it may be confirmed that the thickness Tc of the horizontal region of the blocking layer 143 in the first channel portion CH1 may be the thickness of the second blocking layer 145.

Referring to FIG. 3, it may be confirmed that the thickness of the blocking layer 143 changes discontinuously between the first channel portion CH1 and the second channel portion CH2 with respect to the boundary surface S. For example, the upper thickness Tb of the blocking layer 143 in the first channel portion CH1 may be greater than the lower thickness Td of the blocking layer 143 in the second channel portion CH2. Here, the upper thickness Tb of the blocking layer 143 in the first channel portion CH1 may indicate the thickness of an upper portion of the blocking layer 143 on the side surface of the charge storage layer 142 in the first region, and the lower thickness Td of the blocking layer 143 in the second channel portion CH2 may indicate the thickness of a lower portion of the blocking layer 143 on the side surface of the charge storage layer 142 in the second region.

Referring to FIG. 3, the gate electrodes 130 may include a first conductive layer 132 and a second conductive layer 135. The second conductive layer 135 may surround an upper surface, a lower surface, and a side surface of the first conductive layer 132. The channel structures CH may be in contact with the second conductive layers 135. The gate electrodes 130 include the second conductive layer 135 that may cover side surfaces of the first conductive layers 132 in regions in which the second conductive layers 135 are in contact with the channel structures CH.

The first conductive layer 132 may include a metal material, such as tungsten (W) or molybdenum (Mo). In some example embodiments, the first conductive layer 132 may include polycrystalline silicon or a metal silicide material. The second conductive layer 135 may include tungsten nitride (WN), tantalum nitride (TaN), titanium nitride (TiN), or a combination thereof.

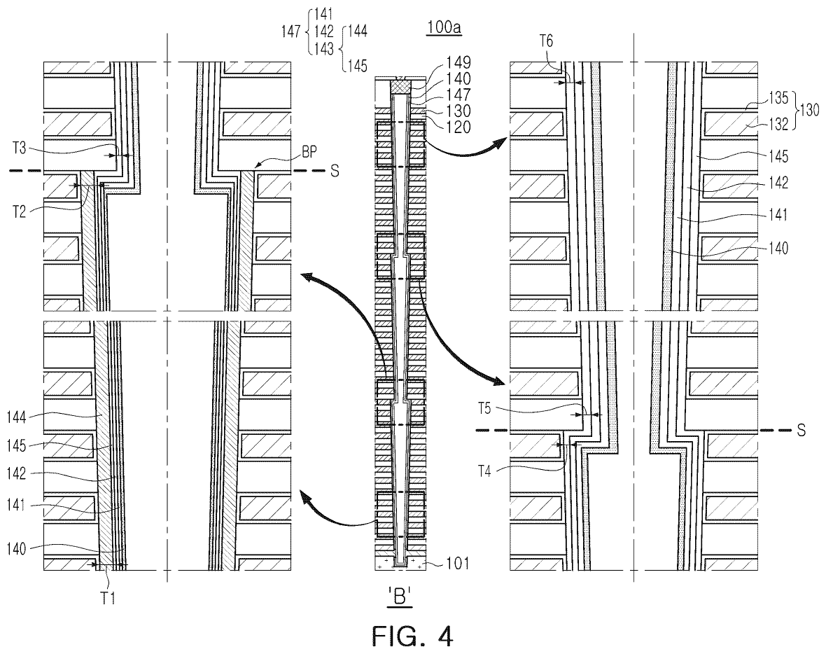

FIG. 4 is an enlarged diagram illustrating a portion of a semiconductor device according to some example embodiments.

Referring to FIGS. 2 to 4, in the first stack structure GS1, which is a lower stack structure, the blocking layer 143 may include a first blocking layer 144 and a second blocking layer 145, and in the second to third stack structures GS2-GS3, which are upper stack structures, the blocking layer 143 may include the second blocking layer 145.

In the first channel portion CH1, a tunneling layer 141, a charge storage layer 142, the second blocking layer 145, and the first blocking layer 144 may be disposed in order between the channel layer 140 and the gate electrodes 130, and in the second to third channel portion CH2-CH3, the tunneling layer 141, the charge storage layer 142, and the second blocking layer 145 may be disposed in order between the channel layer 140 and the gate electrodes 130.

In the process of depositing a channel dielectric layer in a channel hole having a large aspect ratio, step coverage may decrease, and accordingly, the channel dielectric layer 147 including the blocking layer 143 may have a thickness decreasing toward the plate layer 101. Accordingly, the thickness of the blocking layer 143 in each channel portion may decrease toward the plate layer 101. The thickness of the blocking layer 143 in one channel portion may not be conformal and may decrease toward the plate layer 101, and the upper end thickness and the lower end thickness of the blocking layer 143 in one channel portion may not be distinct.

Referring to FIG. 4, the thickness of the blocking layer 143 in the first channel portion CH1 may decrease toward the plate layer 101. For example, the upper thickness T2 of the blocking layer 143 in the first channel portion CH1 may be greater than the lower thickness T1 of the blocking layer 143 in the first channel portion CH1. Since the blocking layer 143 in the first channel portion CH1 includes the first blocking layer 144 and the second blocking layer 145, the thickness of the blocking layer 143 in the first channel portion CH1 may be the sum of the thickness of the first blocking layer 144 and the thickness of the second blocking layer 145 in the first channel portion CH1. In the first channel portion CH1, the blocking layer 143 may have a thickness in a range of about 5 nm to about 10 nm.

In the second channel portion CH2, the thickness of the blocking layer 143 may decrease toward the plate layer 101. For example, the upper thickness T4 of the blocking layer 143 in the second channel portion CH2 may be greater than the lower thickness T3 of the blocking layer 143 in the second channel portion CH2. The blocking layer 143 in the second channel portion CH2 may have a thickness in a range of about 4 nm to about 8 nm.

The thickness of the blocking layer 143 in the third channel portion CH3 may decrease toward the plate layer 101. For example, the upper thickness T6 of the blocking layer 143 in the third channel portion CH3 may be greater than the lower thickness T5 of the blocking layer 143 in the third channel portion CH3. The blocking layer 143 in the third channel portion CH3 may have a thickness in a range of about 4 nm to about 8 nm.

The blocking layer 143 may include a bent portion BP of which a thickness discontinuously changes on a boundary surface S between the first stack structure GS1 and the second stack structure GS2. Since the blocking layer 143 in the first channel portion CH1 further includes the first blocking layer 144, a bent portion BP of which a thickness discontinuously changes on the boundary surface S may be included.

Referring to FIG. 4, it may be confirmed that, in the blocking layer 143, there may be a discontinuous thickness difference between the thickness of the side surface of the first channel portion CH1 and the thickness of the side surface of the second channel portion CH2 with reference to the boundary surface S. For example, the upper thickness T2 of the blocking layer 143 of the first channel portion CH1 may be greater than the lower thickness T3 of the blocking layer 143 of the second channel portion CH2.

According to some example embodiments, in the semiconductor device 100a, the first blocking layer 144 may be deposited as having a relatively great thickness, the upper thickness T2 of the blocking layer 143 in the first channel portion CH1 may be greater than the upper thickness T6 of the blocking layer 143 in the channel portion CH3.

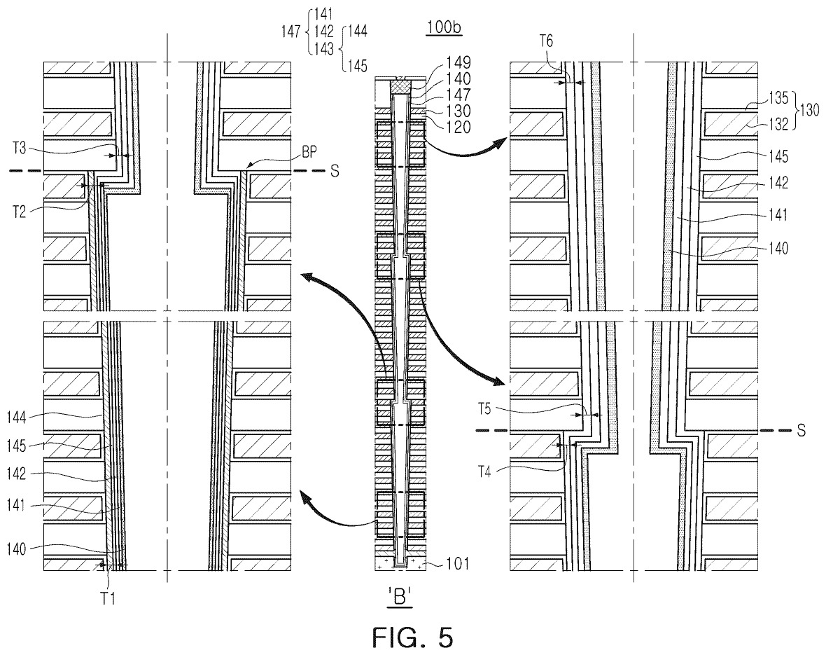

FIG. 5 is an enlarged diagram illustrating a portion of a semiconductor device according to some example embodiments, illustrating a region corresponding to FIG. 4.

Referring to FIG. 5, a semiconductor device 100b according to some example embodiments may be configured the same as or similar to the example described with reference to FIG. 4, other than the configuration in which a first blocking layer 144 is deposited as having a relatively small thickness.

In the semiconductor device 100b according to some example embodiments, the first blocking layer 144 may be deposited as having a relatively small thickness, such that the upper thickness T2 of the blocking layer 143 in the first channel portion CH1 may be smaller than the upper thickness T6 of the blocking layer 143 in the channel portion CH3.

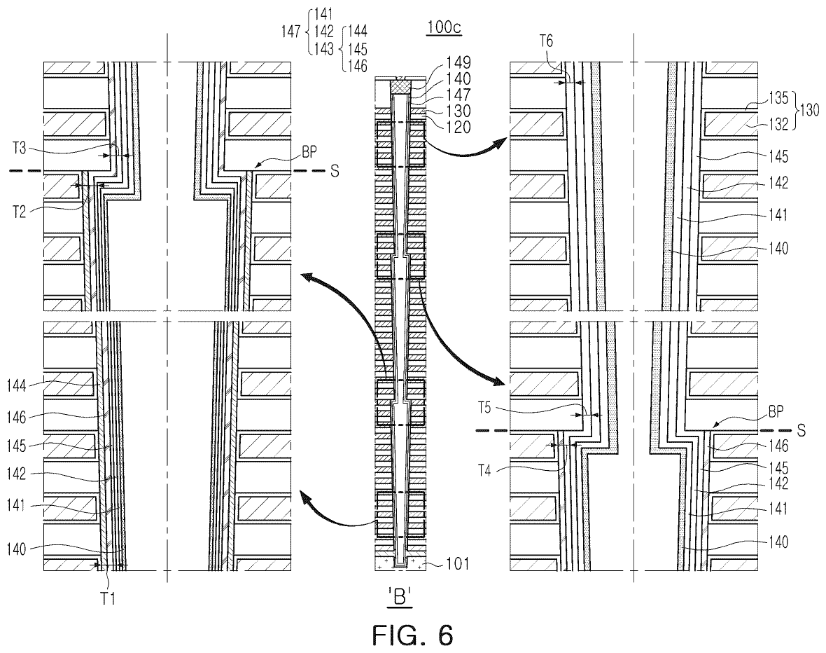

FIG. 6 is an enlarged diagram illustrating a portion of a semiconductor device according to some example embodiments, illustrating a region corresponding to FIG. 4.

Referring to FIG. 6, a semiconductor device 100c according to some example embodiments may be configured the same as or similar to the example described with reference to FIGS. 4 and 5, other than the configuration in which, by depositing an additional blocking layer twice, the blocking layer 143 in the first channel portion CH1 may include the first blocking layer 144, the second blocking layer 145 and a third blocking layer 146, and the blocking layer 143 in the second channel portion CH2 may include the second blocking layer 145 and the third blocking layer 146.

In the semiconductor device 100c in some example embodiments, by further depositing a blocking layer on the first channel portion CH1 of the first stack structure GS1, which is the lowermost end stack structure, the thickness of the blocking layer 143 in the first stack structure GS1 may be increased, such that a difference in thicknesses of the blocking layer 143 in first stack structure GS1 and second stack structure GS2 may be reduced and reliability issues may be addressed. Also, by further depositing a blocking layer on the second channel portion CH2, a difference in thicknesses of the blocking layer 143 in the second stack structure GS2 and the third stack structure GS3 may be reduced, reliability may improve.

Referring to FIG. 6, in the first stack structure GS1, which is a lower stack structure, the blocking layer 143 may include the first blocking layer 144, the second blocking layer 145, and the third blocking layer 146. In the second stack structure GS2, the blocking layer 143 may include the second blocking layer 145 and the third blocking layer 146, and in the third stack structure GS3, the blocking layer 143 may include the second blocking layer 145.

The first blocking layer 144 may refer to a blocking layer deposited after forming the first stack structure GS1 and a channel hole and before filling the channel hole with a sacrificial film. The first blocking layer 144 may not extend to the second channel portion and third channel portions CH2-CH3, and may be disposed on the side surface of the channel hole of the first channel portion CH1. The first blocking layer 144 may include silicon oxide (SiO₂), a high-κ dielectric material, or a combination thereof. The thickness of the first blocking layer 144 may range from about 1 nm to about 5 nm.

The third blocking layer 146 may refer to a blocking layer deposited after forming the first blocking layer 144. For example, the third blocking layer 146 may be formed from a process of depositing before filling a sacrificial film in a channel hole in the second stack structure GS2 after forming the first blocking layer 144. The third blocking layer 146 may be disposed on a side surface of the channel hole of the first to second channel portions CH1-CH2. The third blocking layer 146 may include silicon oxide (SiO₂), a high-κ dielectric material, or a combination thereof. The thickness of the third blocking layer 146 may range from about 1 nm to about 5 nm.

The second blocking layer 145 may indicate a blocking layer deposited after forming the third blocking layer 146. The second blocking layer 145 may be disposed on the side surface of the channel hole of the first to third channel portions CH1-CH3. The second blocking layer 145 may include silicon oxide (SiO₂), a high-κ dielectric material, or a combination thereof.

Referring to FIG. 6, in the first channel portion CH1, a tunneling layer 141, a charge storage layer 142, a second blocking layer 145, a third blocking layer 146, and a first blocking layer 144 may be disposed in order between the channel layer 140 and the gate electrodes 130. In the second channel portion CH2, a tunneling layer 141, a charge storage layer 142, a second blocking layer 145, and a third blocking layer 146 may be disposed in order between the channel layer 140 and the gate electrodes 130, and in the third channel portion CH3, a tunneling layer 141, a charge storage layer 142, and a second blocking layer 145 may be disposed in order between the channel layer 140 and the gate electrodes 130.

Although the processing orders of the first to third blocking layers 144, 145, and 146 may be different, when the layers may include the same material, a boundary between the layers may not be distinct. Accordingly, the first to third blocking layers 144, 145, and 146 may be recognized as a single blocking layer 143 without distinction. However, in FIG. 6, the first to third blocking layers 144, 145, and 146 may be distinct from each other for ease of description.

The blocking layer 143 may have a first region penetrating the first stack structure GS1, a second region penetrating the second stack structure GS2, and a third region penetrating the third stack structure GS3. The thickness of an upper portion of the blocking layer 143 on the side surface of the charge storage layer in the first region may be greater than the thickness of a lower portion of the blocking layer on the side surface of the charge storage layer in the second region. The thickness of the upper portion of the blocking layer 143 on the side surface of the charge storage layer in the second region may be greater than the thickness of the lower portion of the blocking layer 143 on the side surface of the charge storage layer in the third region.

The upper surface partially in contact with the second stack structures GS2 of the first blocking layer 144 in the first region and the upper surface partially in contact with the second stack structures GS2 of the third blocking layer 146 may be coplanar. The upper surface partially in contact with the third stack structures GS3 of the third blocking layer 146 in the second region and the upper surface partially in contact with the third stack structures GS2 of the second blocking layer 145 may be coplanar.

The blocking layer 143 may include a bent portion BP of which the thickness discontinuously changes on a boundary surface S between the first stack structure GS1 and the second stack structure GS2. Since the blocking layer 143 in the first channel portion CH1 further includes the first blocking layer 144 and the third blocking layer 146, the bent portion BP of which the thickness discontinuously changes on the boundary surface S may be included. Also, since the blocking layer 144 in the second channel portion CH2 further includes the third blocking layer 146, the bent portion BP of which the thickness discontinuously changes on the boundary surface S may be included.

Referring to FIG. 6, it may be confirmed that the thickness of the blocking layer 143 discontinuously changes between the first channel portion CH1 and the second channel portion CH2 with respect to the boundary surface S. For example, the upper thickness T2 of the blocking layer 143 in the first channel portion CH1 may be greater than the lower thickness T3 of the blocking layer 143 in the second channel portion CH2.

The upper thickness T2 of the blocking layer 143 in the first channel portion CH1 may be the sum of the thickness of the first blocking layer 144, the thickness of the second blocking layer 145, and the thickness of the third blocking layer 146, and the lower thickness T3 of the blocking layer 143 in the second channel portion CH2 may be the sum of the thickness of the second blocking layer 145 and the thickness of the third blocking layer 146.

Also, referring to FIG. 6, it may be confirmed that the thickness of the blocking layer 143 discontinuously changes between the second channel portion CH2 and the third channel portion CH3 with respect to the boundary surface S, confirming that there is a discontinuous thickness difference. For example, the upper thickness T4 of the blocking layer 143 in the second channel portion CH2 may be greater than the lower thickness T5 of the blocking layer 143 in the third channel portion CH3.

The upper thickness T4 of the blocking layer 143 in the second channel portion CH2 may be the sum of the side surface thickness of the second blocking layer 145 and the side surface thickness of the third blocking layer 146, and the lower thickness T5 of the blocking layer 143 in the third channel portion CH3 may be the thickness of the second blocking layer 145.

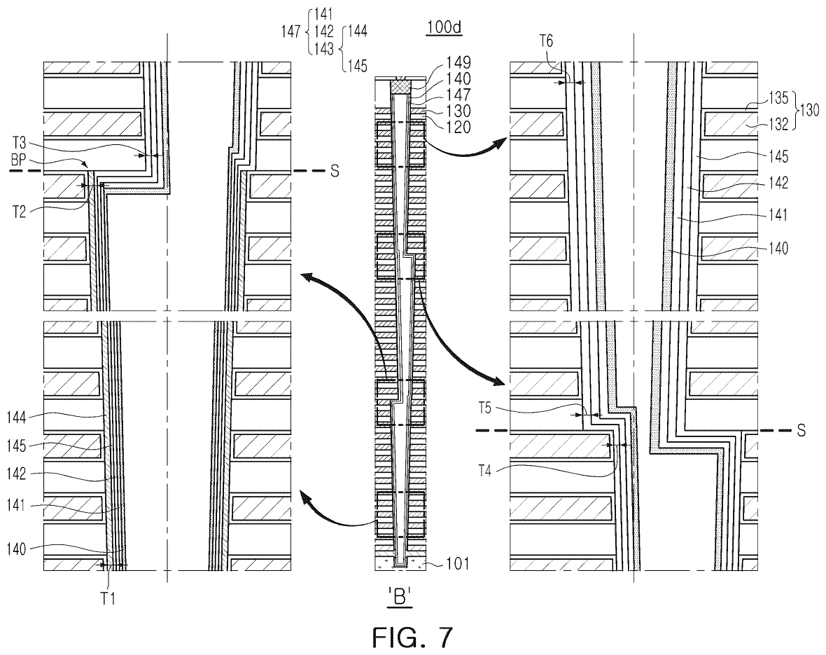

FIG. 7 is an enlarged diagram illustrating a portion of a semiconductor device according to some example embodiments, illustrating a region corresponding to FIG. 4.

Referring to FIG. 7, a semiconductor device 100d according to some example embodiments may be configured the same as or similar to the example described with reference to FIGS. 4 to 6, other than the configuration in which at least a portion of channel structures CH is shifted.

In each of the channel structures CH, k number of channel portions CH1-CHk (k is a natural number such as 1, 2, 3, 4, or the like) penetrating k number of stack structures GS1-GSk of the gate electrodes 130 are connected to each other, and in some example embodiments, the first to third channel portions CH1-CH3 penetrating three stack structures GS1-GS3, respectively, may be connected to each other. The connection portion between the first to third channel portions CH1-CH3 may have a bent portion BP due to a difference or a change in width. At least a portion of the first to third channel portions CH1-CH3 may be shifted and miss-aligned. Accordingly, the centers of the widths of the upper surfaces of the first to third channel portions CH1-CH3 may be shifted and may not be positioned linearly.

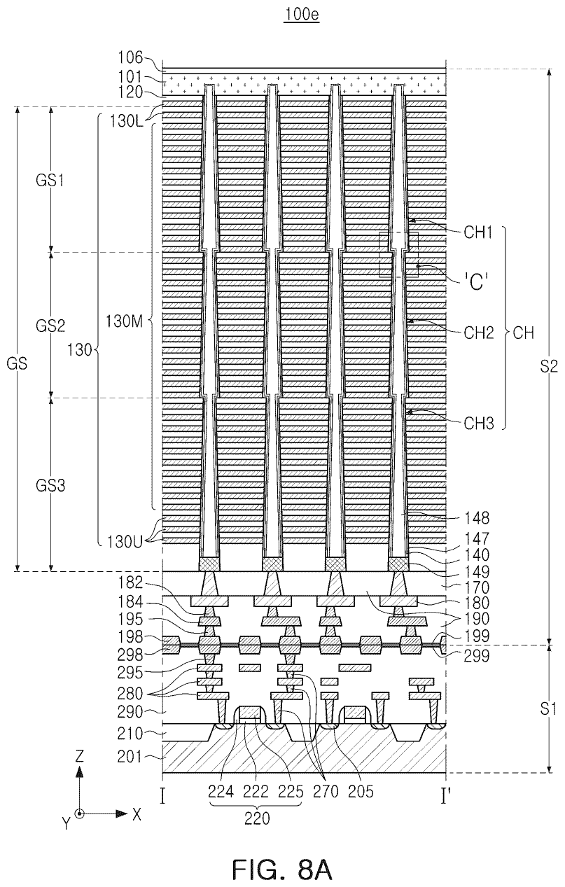

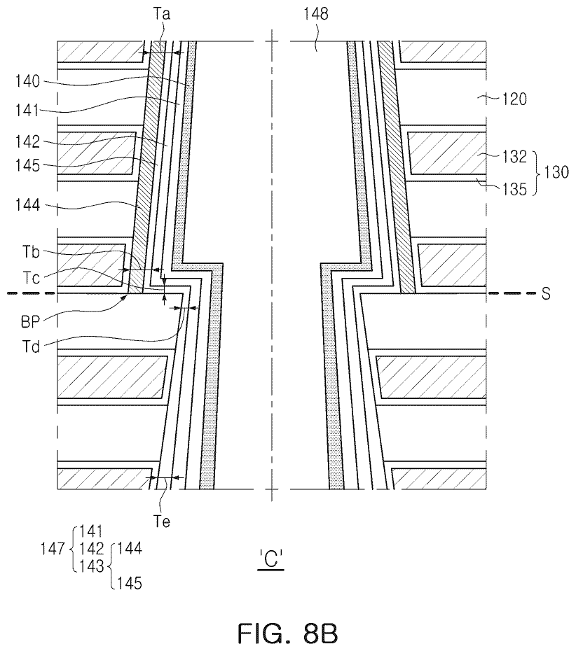

FIG. 8A is a cross-sectional diagram illustrating a semiconductor device according to some example embodiments, illustrating a region corresponding to FIG. 2. FIG. 8B is a cross-sectional diagram illustrating a semiconductor device according to some example embodiments, illustrating region ‘C’ in FIG. 8B.

Referring to FIGS. 8A and 8B, a semiconductor device 100e according to some example embodiments may be configured the same as or similar to the example described with reference to FIGS. 1 to 7, other than the configuration in which the first semiconductor structure S1 and the second semiconductor structure S2 are bonded to each other by a wafer bonding method.

Referring to FIGS. 8A and 8B, the semiconductor device 100e may include the first semiconductor structure S1 and the second semiconductor structure S2 bonded to each other by a wafer bonding method.

The description of the peripheral circuit region PERI described above with reference to FIGS. 1 and 2 may be applied to the first semiconductor structure S1. However, the first semiconductor structure S1 may further include a bonding structure, first bonding vias 295, first bonding metal layers 298, and a first bonding insulating layer 299. The first bonding vias 295 may be disposed on an upper portion of circuit interconnection lines 280 disposed in an uppermost portion and may be connected to the circuit interconnection lines 280. The first bonding metal layers 298 may have at least a portion connected to the first bonding vias 295 on the first bonding vias 295. The first bonding metal layers 298 may be connected to the second bonding metal layers 198 of the second semiconductor structure S2. The first bonding metal layers 298 may provide an electrical connection path together with the second bonding metal layers 198 according to bonding between the first semiconductor structure S1 and the second semiconductor structure S2. A portion of the first bonding metal layers 298 may be disposed only for bonding without being connected to the circuit interconnection lines 280 of the lower portion. The first bonding vias 295 and the first bonding metal layers 298 may include a conductive material, for example, copper (Cu). The first bonding insulating layer 299 may be disposed around the first bonding metal layers 298. The first bonding insulating layer 299 may also function as a diffusion barrier for the first bonding metal layers 298 and may include, for example, at least one of SiN, SiON, SiCN, SiOC, SiOCN, and SiO.

Unless otherwise indicated, the description of the memory cell region CELL described above with reference to FIGS. 1 and 2 may be applied to the second semiconductor structure S2. The second semiconductor structure S2 may further include lower contact plugs 182 and cell interconnection lines 184, which is a cell interconnection structure, and may further include second bonding vias 195, second bonding metal layers 198, and second bonding insulating layer 199, which is a bonding structure. The second semiconductor structure S2 may further include a passivation layer 106 covering an upper surface of the plate layer 101.

Lower contact plugs 182 may be connected to bitlines 180, and cell interconnection lines 184 may be connected to lower contact plugs 182. However, in some example embodiments, the number of layers and arrangement of contact plugs and interconnection lines included in the cell interconnection structure may be varied. The lower contact plugs 182 and the cell interconnection lines 184 may be formed of a conductive material, for example, at least one of tungsten (W), aluminum (Al), and copper (Cu).

Second bonding vias 195 and second bonding metal layers 198 may be disposed below the cell interconnection lines 184 disposed in the lowermost portion. The second bonding vias 195 may connect the cell interconnection lines 184 to the second bonding metal layers 198, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material, for example, copper (Cu). The second bonding insulating layer 199 may include at least one of, for example, SiO, SiN, SiCN, SiOC, SiON, and SiOCN.

The first and second semiconductor structures S1 and S2 may be bonded to each other by bonding between the first bonding metal layers 298 and the second bonding metal layers 198 and by bonding between the first bonding insulating layer 299 and the second bonding insulating layer 199. The bonding between the first bonding metal layers 298 and the second bonding metal layers 198 may be, for example, copper (Cu)-copper (Cu) bonding, and the bonding between the first bonding insulating layer 299 and the second bonding insulating layer 199 may be, for example, dielectric-dielectric bonding, such as SiCN-SiCN bonding. The first and second semiconductor structures S1 and S2 may be bonded to each other by hybrid bonding including copper (Cu)-copper (Cu) bonding and dielectric-dielectric bonding.

The passivation layer 106 may be disposed on the upper surface of the plate layer 101 and may protect the semiconductor device 100e. The passivation layer 106 may include at least one of an insulating material, for example, silicon oxide, silicon nitride, and silicon carbide, and may include a plurality of insulating layers in some example embodiments.

In some example embodiments, the second semiconductor structure S2 may not include the first and second horizontal conductive layers 102 and 104 (see FIG. 2). The channel structures CH may be directly connected to the plate layer 101 in a state in which the channel layers 140 are exposed through an upper end. However, the electrical connection between the channel structures CH and the common source line may be varied in some example embodiments, and the channel structures CH and the source structure SS may be configured the same as the example embodiment in FIG. 2.

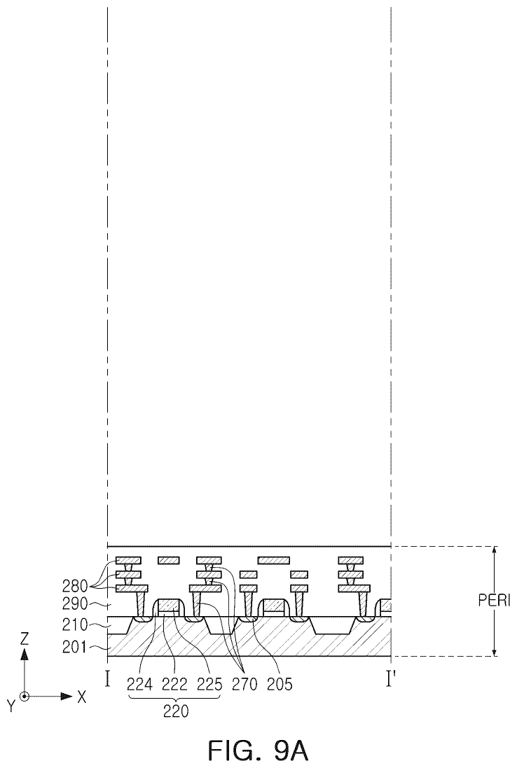

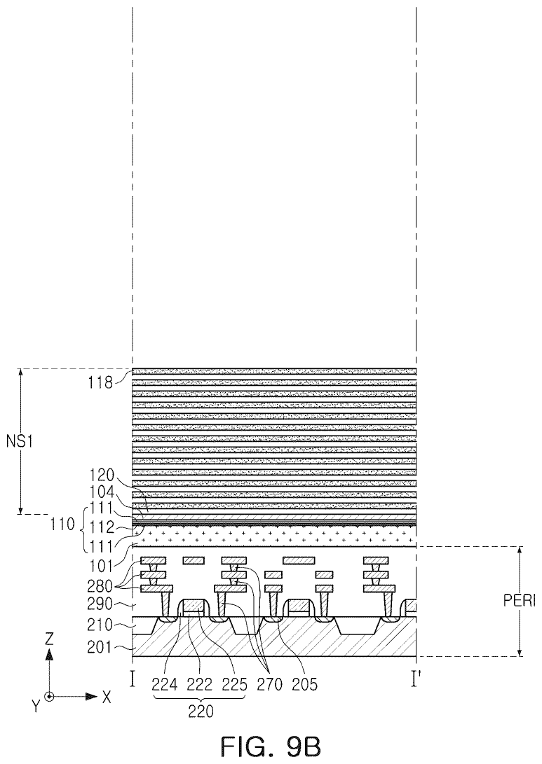

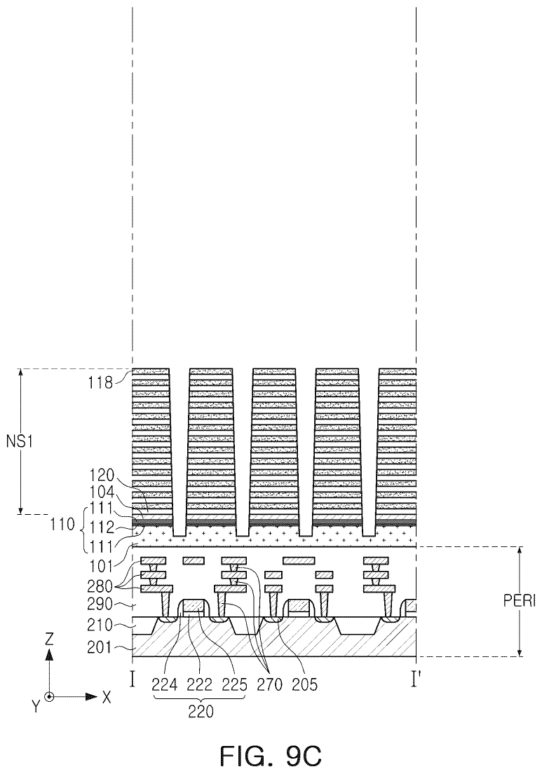

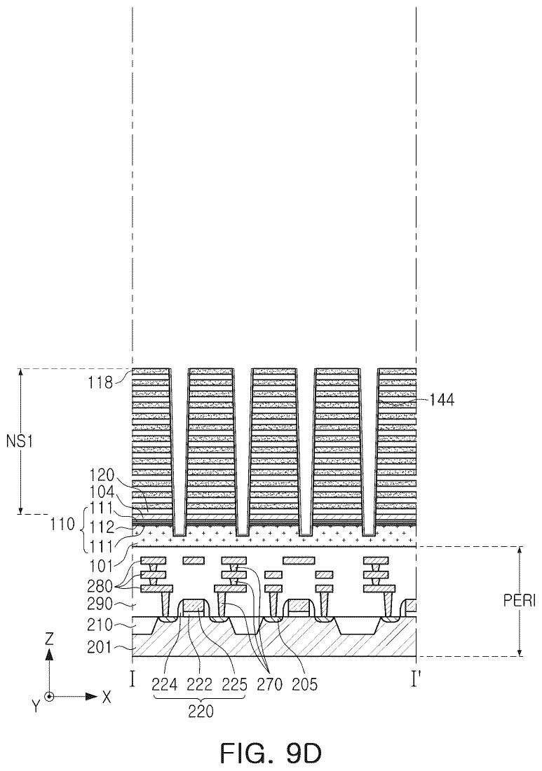

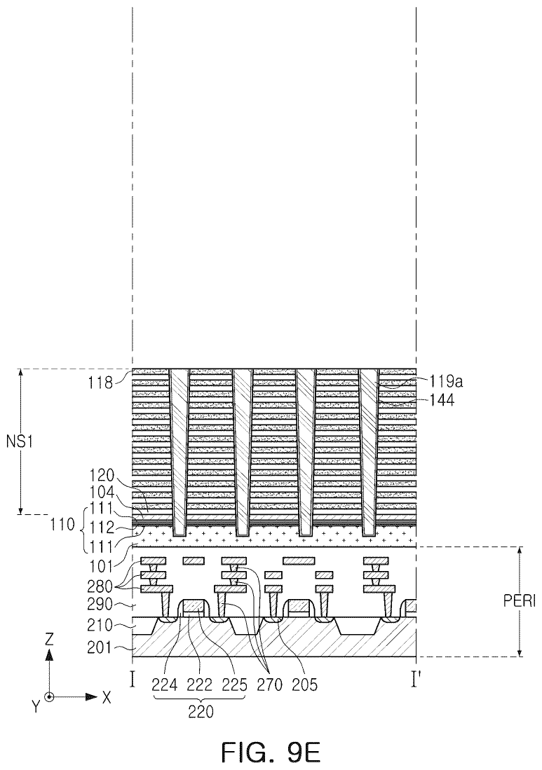

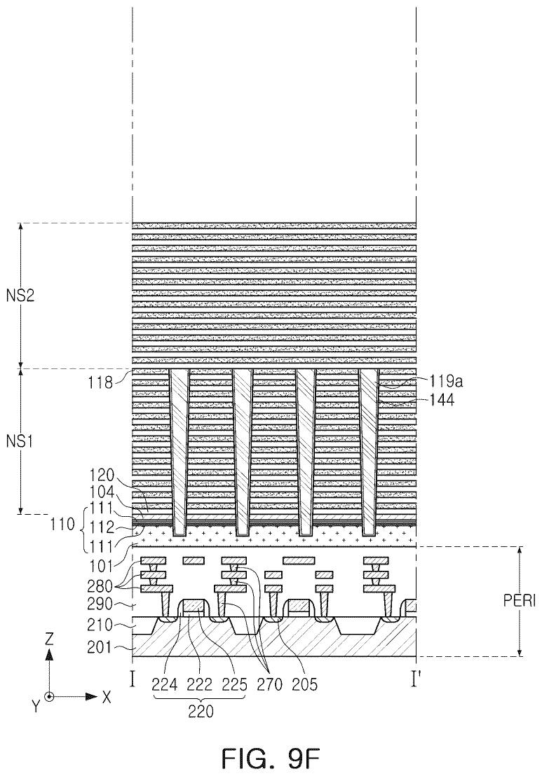

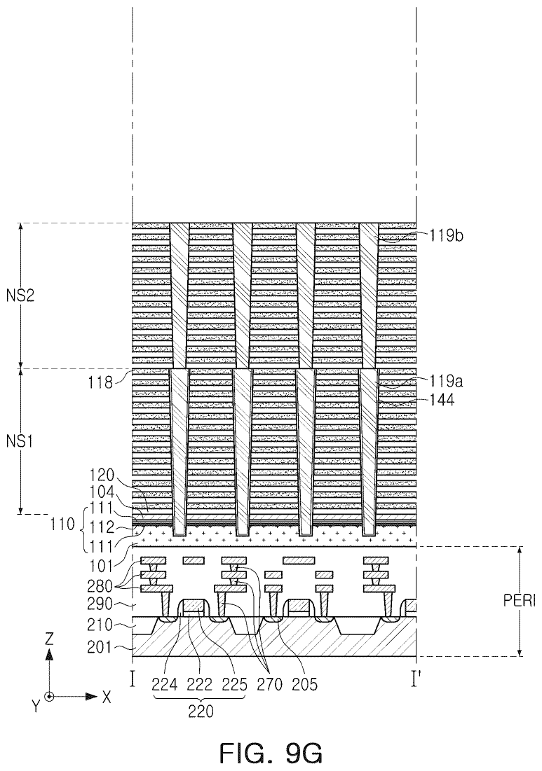

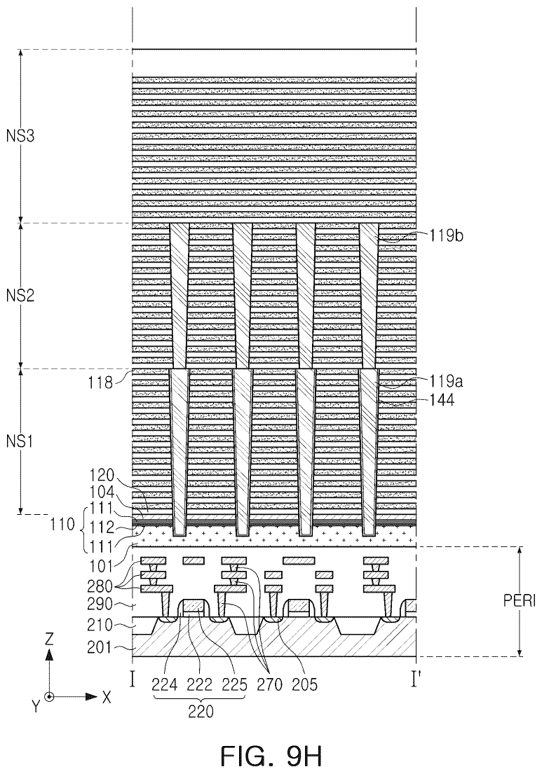

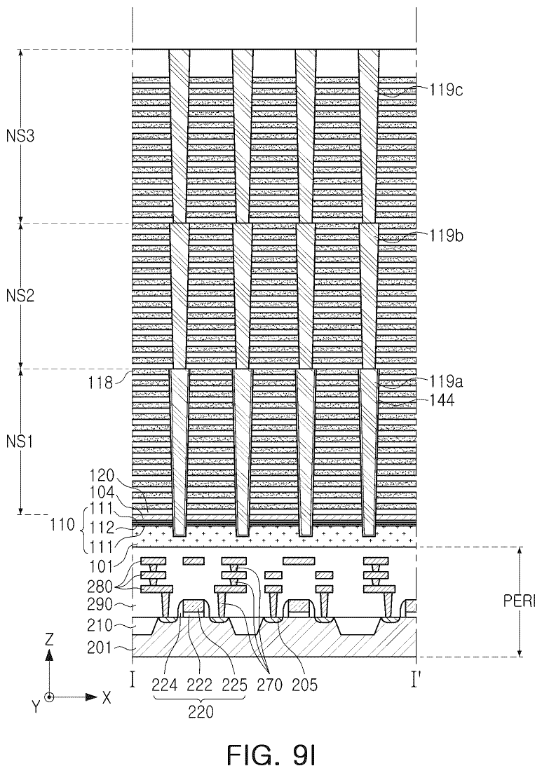

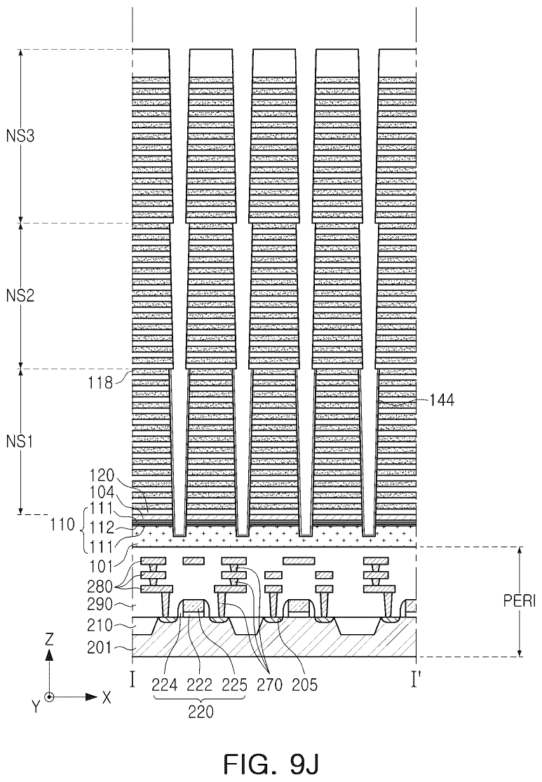

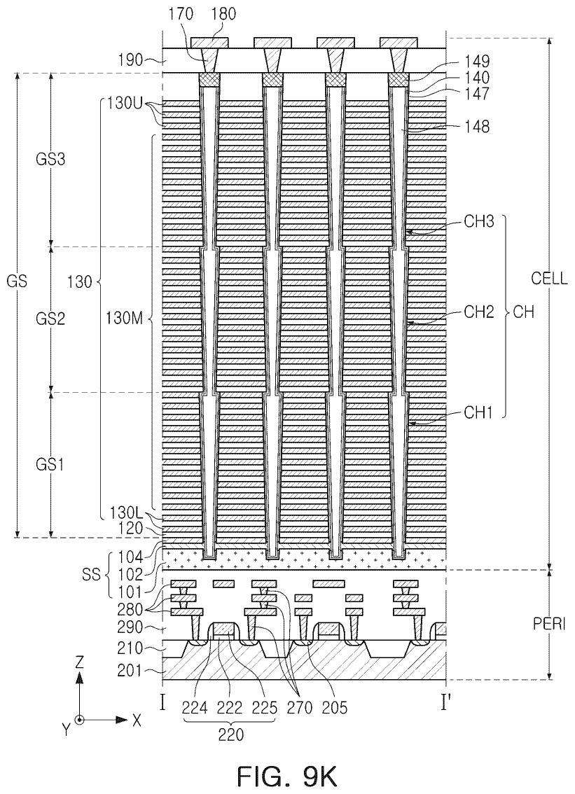

FIGS. 9A to 9K are cross-sectional diagrams illustrating a method of manufacturing a semiconductor device according to some example embodiments, illustrating regions corresponding to FIG. 2.

Referring to FIG. 9A, circuit elements 220, a circuit interconnection structure, and a peripheral region insulating layer 290 included in a peripheral circuit region PERI may be formed on a substrate 201.

First, device isolation layers 210 may be formed in the substrate 201, and the circuit channel dielectric layer 222 and the circuit gate electrode 225 may be formed in order on the substrate 201. The device isolation layers 210 may be formed, for example, by a shallow trench isolation (STI) process. The circuit channel dielectric layer 222 and the circuit gate electrode 225 may be formed using atomic layer deposition (ALD) or chemical vapor deposition (CVD). The circuit channel dielectric layer 222 may be formed of silicon oxide, and the circuit gate electrode 225 may be formed of at least one of polycrystalline silicon or a metal silicide layer, but some example embodiments thereof are not limited thereto. Thereafter, a spacer layer 224 and impurity regions 205 may be formed on both sides of the circuit channel dielectric layer 222 and the circuit gate electrode 225. In some example embodiments, the spacer layer 224 may include a plurality of layers. The impurity regions 205 may be formed by performing an ion implantation process.

Among the circuit interconnection structures, the circuit contact plugs 270 may be formed by forming a portion of a peripheral region insulating layer 290, partially removing the layer by etching, and filling a conductive material therein. The circuit interconnection lines 280 may be formed, for example, by depositing a conductive material and patterning the material.

The peripheral region insulating layer 290 may include a plurality of insulating layers. The peripheral region insulating layer 290 may become a portion of each of operations for forming the circuit interconnection structure. Accordingly, a peripheral circuit region PERI may be formed.

Referring to FIG. 9B, a first molded structure NS1 may be formed by forming a plate layer 101, a horizontal sacrificial layer 110, and a second horizontal conductive layer 104, in which a memory cell region CELL is provided, on the peripheral circuit region PERI, and alternately stacking sacrificial insulating layers 118 and interlayer insulating layers 120.

The plate layer 101 may be formed on the peripheral region insulating layer 290. The plate layer 101 may be formed of, for example, polycrystalline silicon and may be formed by a CVD process. Polycrystalline silicon forming the plate layer 101 may include impurities.

First and second horizontal insulating layers 111 and 112 included in the horizontal sacrificial layer 110 may be alternately stacked on the plate layer 101. The horizontal sacrificial layer 110 may be replaced with the first horizontal conductive layer 102 in FIG. 2 through a subsequent process. The first horizontal insulating layers 111 may include a material different from that of the second horizontal insulating layer 112. For example, the first horizontal insulating layers 111 may be formed of the same material as the interlayer insulating layers 120, and the second horizontal insulating layer 112 may be formed of the same material as the sacrificial insulating layers 118. The second horizontal conductive layer 104 may be formed on the horizontal sacrificial layer 110.

The first molded structure NS1 may be formed on the second horizontal conductive layer 104 in a position corresponding to the first stack structure GS1 in FIG. 2.

The sacrificial insulating layers 118 may be replaced with a portion of the gate electrodes 130 (see FIG. 2) through a subsequent process. The sacrificial insulating layers 118 may be formed of a material different from that of the interlayer insulating layers 120 and may be formed of a material etched with etch selectivity under specific etch conditions with respect to the interlayer insulating layers 120. For example, the interlayer insulating layer 120 may be formed of at least one of silicon oxide and silicon nitride, and the sacrificial insulating layers 118 may be formed of a material different from that of the interlayer insulating layer 120, a material selected from among silicon, silicon oxide, silicon carbide, and silicon nitride. In some example embodiments, the thicknesses of the interlayer insulating layers 120 may not be the same. The thicknesses of the interlayer insulating layers 120 and the sacrificial insulating layers 118 and the number of films included therein may be varied from the illustrated example.

Referring to FIG. 9C, channel holes may be formed in positions corresponding to the first channel structures CH1.

The channel holes may be formed to penetrate the first molded structure NS1. The channel holes penetrating the first molded structure NS1 may be formed in positions corresponding to the first channel structures CH1 using an etching process.

The channel holes penetrating the first molded structure NS1 may penetrate the stack structure GS and may extend in the Z-direction, and may be connected to the plate layer 101. The channel holes penetrating the first molded structure NS1 may have a pillar shape and may have an inclined side surface having a width decreasing toward the plate layer 101 depending on an aspect ratio.

Referring to FIG. 9D, the first blocking layer 144 may be formed on an inner side surface of the channel holes penetrating the first molded structure NS1.

The first blocking layer 144 may be formed by depositing a material in the channel holes and performing a planarization process. The first blocking layer 144 may include silicon oxide (SiO₂), a high-κ dielectric material, or a combination thereof. The thickness of the first blocking layer 144 may range from about 1 nm to about 5 nm.

Referring to FIG. 9E, the first vertical sacrificial layers 119a may be formed in a position corresponding to the first channel structures CH1.

The first vertical sacrificial layers 119a may be formed on the first blocking layer 144 by forming holes to penetrate the first molded structure NS1, depositing a sacrificial layer material in the holes, and performing a planarization process. The first vertical sacrificial layers 119a may include, for example, carbon or a carbon-based material, but some example embodiments thereof are not limited thereto.

Referring to FIG. 9F, a second molded structure NS2 may be formed by alternately stacking the sacrificial insulating layers 118 and the interlayer insulating layers 120.

Referring to FIG. 9F, the second molded structure NS2 may be formed in the same manner as described with reference to FIG. 9B, other than the configuration in which the second molded structure NS2 is formed in a position corresponding to the second stack structure GS2 in FIG. 2.

Referring to FIG. 9G, channel holes may be formed in a position corresponding to the second channel structures CH2, and second vertical sacrificial layers 119b may be formed in the formed channel holes.

The channel holes may be formed to penetrate the second molded structure NS2. The channel holes penetrating the second molded structure NS2 may be formed in a position corresponding to the second channel structures CH2 using an etching process.

The channel holes penetrating the second molded structure NS2 may penetrate the stack structure GS, may extend in the Z-direction and may be connected to the first vertical sacrificial layers 119a. The channel holes penetrating the second molded structure NS2 may have a columnar shape and may have an inclined side surface having a width decreasing toward the plate layer 101 depending on an aspect ratio.

The second vertical sacrificial layers 119b may be formed by forming the channel holes to penetrate the second molded structure NS2, depositing sacrificial layer material on the channel holes, and performing a planarization process. The second vertical sacrificial layers 119b may include, for example, carbon or a carbon-based material, but some example embodiments thereof are not limited thereto.

Referring to FIG. 9H, a third molded structure NS3 may be formed by alternately stacking sacrificial insulating layers 118 and interlayer insulating layers 120.

Referring to FIG. 9H, the third molded structure NS3 may be formed in the same manner as described with reference to FIG. 9B, other than the configuration in which the third molded structure NS3 is formed in a position corresponding to the third stack structure GS3 in FIG. 2.

Referring to FIG. 9I, channel holes may be formed in positions corresponding to the third channel structures CH3, and third vertical sacrificial layers 119c may be formed in the formed channel holes.

Referring to FIG. 9I, the third vertical sacrificial layers 119c may be formed in the same manner as described with reference to FIG. 9G, other than the configuration in which the third vertical sacrificial layers 119c is formed in a position corresponding to the third channel structure CH3 in FIG. 2.

The third vertical sacrificial layers 119c may be formed by forming the channel holes to penetrate the third molded structure NS3, depositing sacrificial layer material in the channel holes, and performing a planarization process. The third vertical sacrificial layers 119c may include, for example, carbon or a carbon-based material, but some example embodiments thereof are not limited thereto.

Referring to FIG. 9J, the first to third vertical sacrificial layers 119a, 119b, and 119c may be removed using an ashing process using oxygen.

Relatively oxygen in high temperature may be used to remove the first to third vertical sacrificial layers 119a, 119b, and 119c. For example, oxygen in high temperature of about 100° C. to about 400° C. may be used.

By removing the first to third vertical sacrificial layers 119a, 119b, and 119c through an ashing process using high-temperature oxygen, damage to the deposited first blocking layer 144 may be limited and/or prevented as compared to a method of removing the first to third vertical sacrificial layers 119a, 119b, and 119c using an etchant, which may be because the first blocking layer 144 includes silicon oxide (SiO₂), and silicon oxide (SiO₂) may not react well with high-temperature oxygen. Accordingly, the first to third vertical sacrificial layers 119a, 119b, and 119c may be removed without damage to the first blocking layer 144, improving reliability of the semiconductor device.

Referring to FIG. 9K, channel structures CH may be formed by forming hole-shaped channel holes by removing the first to third vertical sacrificial layers 119a, 119b, and 119c, depositing at least a portion of the channel dielectric layer 147, the channel layer 140, and the channel filled insulating layer 148 in order within the channel holes, and forming channel pad 149.

The sacrificial insulating layers 118 may be selectively removed with respect to the interlayer insulating layers 120 and the channel structures CH, for example, by wet etching. The gate electrodes 130 may be formed by depositing a conductive material in the regions from which the sacrificial insulating layers 118 have been removed. The conductive material may include a metal, polysilicon, or a metal silicide.

The channel dielectric layer 147 may be formed to have a uniform thickness using an ALD or CVD process. In this process, the entirety or a portion of the channel dielectric layer 147 may be formed, and a portion extending vertically along the channel structures CH to the plate layer 101 may be formed in the process. The channel layer 140 may be formed on the channel dielectric layer 147 within the channel holes. The channel filled insulating layer 148 may be formed to fill the channel holes and may be an insulating material. The channel pad 149 may be formed after a portion of the channel filled insulating layer 148 is removed. The channel pad 149 may be formed of a conductive material and may be formed of, for example, polycrystalline silicon. The description of a process not relevant to the example embodiment may not be provided below.

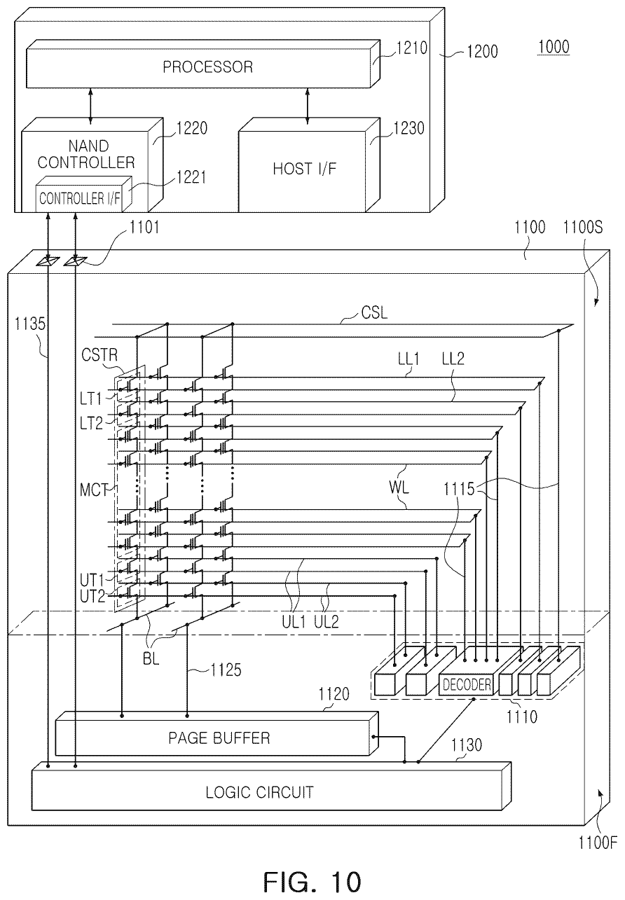

FIG. 10 is a diagram illustrating a data storage system including a semiconductor device according to some example embodiments.

Referring to FIG. 10, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 8. The semiconductor device 1100 may include a first structure 1100F and a second structure 1100S on the first structure 1100F. In some example embodiments, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CUS_SL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example embodiments.

In some example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In some example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In some example embodiments, the data storage system 1000 may include a plurality of semiconductor devices 1100, and in some example embodiments, the controller 1200 may control the plurality of semiconductor devices 1100.

The processor 1210 may control overall operation of the data storage system 1000 including the controller 1200. The processor 1210 may operate according to desired (and/or alternatively predetermined) firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

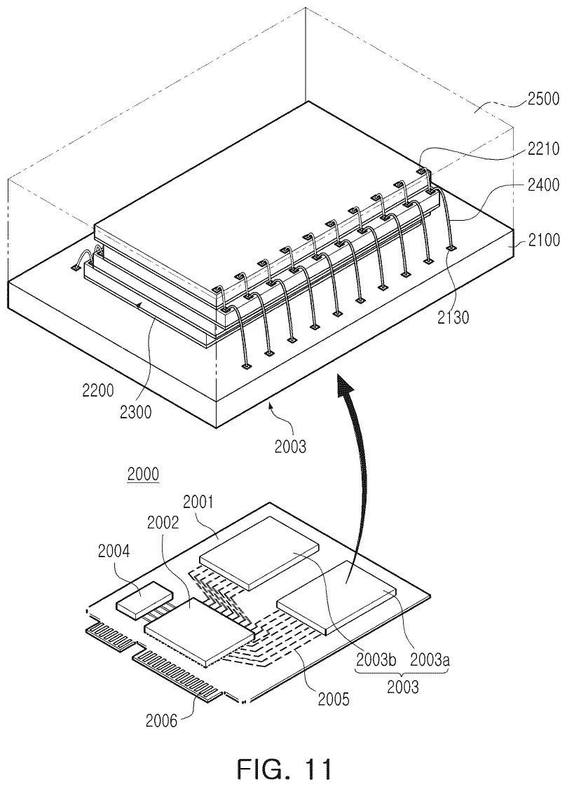

FIG. 11 is a perspective diagram illustrating a data storage system including a semiconductor device according to some example embodiments.

Referring to FIG. 11 a data storage system 2000 in some example embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In some example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In some example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 10. Each of the semiconductor chips 2200 may include gate stack structures and channel structures such as described with respect to FIGS. 1-8. Each of the semiconductor chips 2200 may include the semiconductor device described in the aforementioned example embodiment with reference to FIGS. 1 to 8B.

In some example embodiments, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In some example embodiments, the controller 2002 and the semiconductor chips 2200 may be included in a single package. In some example embodiments, the controller 2002 and the semiconductor chips 2200 may be mounted on an interposer substrate different from the main board 2001, and the controller 2002 and the semiconductor chips 2200 may be connected to each other by interconnection formed on the interposer substrate.

According to the aforementioned some example embodiments, by further depositing a blocking layer in the lower end stack structure and increasing a thickness of the blocking layer in the lower end stack structure, a difference in the thickness of the blocking layer between the lower end stack structure and the upper end stack structure may be reduced, and a semiconductor device having improved reliability and a data storage system including the same may be provided.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While some example embodiments have been illustrated and described above, it will be apparent to those skilled in the art that modifications and variations could be made without departing from the scope of the present disclosure as defined by the appended claims.

What is claimed is:

1. A semiconductor device, comprising:
a first semiconductor structure including a substrate, circuit elements on the substrate, and circuit interconnection lines on the circuit elements; and
a second semiconductor structure on the first semiconductor structure,
wherein the second semiconductor structure includes
a plate layer;
a first stack structure and a second stack structure stacked in a first direction perpendicular to an upper surface of the plate layer, the first stack structure being on the upper surface of the plate layer,
the first stack structure and the second stack structure including gate electrodes and interlayer insulating layers alternately stacked on each other in the first direction,
the first stack structure including a first lower gate electrode, first memory gate electrodes, and a first upper gate electrode sequentially stacked, and
the second stack structure including a second lower gate electrode, second memory gate electrodes, and a second upper gate electrode sequentially stacked; and
a channel structure including a plurality of channel portions penetrating the first stack structure and the second stack structure, respectively, the plurality of channel portions being connected to each other in the first direction,
wherein the channel structure includes
a filling insulating layer extending in the first direction within the plurality of channel portions;
a channel layer on a side surface of the filling insulating layer opposing the gate electrodes and the interlayer insulating layers; and
a channel dielectric layer including a tunneling layer, a charge storage layer, and a blocking layer, in order between the channel layer and the gate electrodes,
wherein the blocking layer includes a first region penetrating the first stack structure and a second region penetrating the second stack structure, and
wherein a first thickness of an upper portion of the blocking layer on a side surface of the charge storage layer in the first region is greater than a second thickness of a lower portion of the blocking layer on a side surface of the charge storage layer in the second region.

2. The semiconductor device of claim 1, wherein the blocking layer includes a bent portion having a thickness that changes discontinuously on a boundary surface between the first region and the second region.

3. The semiconductor device of claim 1, wherein, in the first region, a third thickness of the blocking layer on an upper surface of the charge storage layer is less than the first thickness.

4. The semiconductor device of claim 1, wherein, in the first region, a third thickness of the blocking layer decreases as the blocking layer extends toward the plate layer.

5. The semiconductor device of claim 1, wherein, in the second region, a third thickness of the blocking layer decreases as the blocking layer extends toward the plate layer.

6. The semiconductor device of claim 1, wherein the first thickness of the blocking layer is 5 nm to 10 nm.

7. The semiconductor device of claim 1, wherein the second thickness of the blocking layer is 4 nm to 8 nm.

8. The semiconductor device of claim 1, wherein, in the first region, the blocking layer includes a first blocking layer and a second blocking layer including different materials.

9. The semiconductor device of claim 8, wherein, in the first region, an upper surface of the first blocking layer that contacts a portion of the second stack structure, and an upper surface of the second blocking layer that contacts another portion of the second stack structure, are coplanar.

10. A semiconductor device, comprising:
a plate layer;
a plurality of stack structures including gate electrodes and interlayer insulating layers alternately stacked in a first direction on the plate layer; and
a channel structure including a plurality of channel portions penetrating the plurality of stack structures, respectively, the plurality of channel portions being connected to each other in the first direction,
wherein the channel structure includes
a filling insulating layer extending in the first direction within the plurality of channel portions,
a channel layer on a side surface of the filling insulating layer opposing the gate electrodes and the interlayer insulating layers, and
a channel dielectric layer including a tunneling layer, a charge storage layer, and a blocking layer in order between the channel layer and the gate electrodes,
wherein, in a channel portion of the plurality of channel portions on a lowermost end of the channel structure, the blocking layer includes a bent portion having a thickness that changes discontinuously between a vertical region in an extension direction of the channel portion on the lowermost end of the channel structure and a horizontal region extending in a second direction perpendicular to the first direction, and
wherein a thickness of the vertical region is greater than a thickness of the horizontal region.

11. The semiconductor device of claim 10, wherein the bent portion is on a boundary surface between a lowermost stack structure of the plurality of stack structures and a stack structure of the plurality of stack structures on the lowermost stack structure.

12. The semiconductor device of claim 10, wherein a first thickness of an upper portion of the blocking layer on a first side surface of the charge storage layer in a lowermost stack structure of the plurality of stack structures is greater than a second thickness of a lower portion of the blocking layer on a second side surface of the charge storage layer in a stack structure of the plurality of stack structures on the lowermost stack structure.

13. The semiconductor device of claim 10, wherein, in a lowermost stack structure of the plurality of stack structures, a first thickness of an upper portion of the blocking layer on a side surface of the charge storage layer is greater than a second thickness of a lower portion of the blocking layer on the side surface of the charge storage layer.

14. The semiconductor device of claim 10, wherein, in a stack structure of the plurality of stack structures on a lowermost stack structure of the plurality of stack structures, a first thickness of an upper portion of the blocking layer on a side surface of the charge storage layer is greater than a second thickness of a lower portion of the blocking layer on the side surface of the charge storage layer.

15. The semiconductor device of claim 10, wherein, in a lowermost stack structure of the plurality of stack structures, a first thickness of the blocking layer is 5 nm to 10 nm.

16. The semiconductor device of claim 10, wherein, in a stack structure of the plurality of stack structures on a lowermost stack structure of the plurality of stack structures, a first thickness of the blocking layer is 4 nm to 8 nm.

17. The semiconductor device of claim 10, wherein, in a lowermost stack structure of the plurality of stack structures, the blocking layer includes a first blocking layer and a second blocking layer including different materials.

18. The semiconductor device of claim 17, wherein, in the lowermost stack structure, an upper surface of the first blocking layer that contacts a portion of a stack structure of the plurality of stack structures on the lowermost stack structure, and an upper surface of the second blocking layer that contacts another portion of the stack structure of the plurality of stack structures on the lowermost stack structure, are coplanar.

19. A data storage system, comprising:
a semiconductor storage device including a first semiconductor structure, a second semiconductor structure on a surface of the first semiconductor structure, and an input/output pad electrically connected to circuit elements of the first semiconductor structure; and
a controller electrically connected to the semiconductor storage device through the input/output pad, the controller configured to control the semiconductor storage device,
wherein the second semiconductor structure includes
a plate layer;
a first stack structure and a second stack structure stacked in a first direction perpendicular to an upper surface of the plate layer, the first stack structure being on the upper surface of the plate layer,
the first stack structure and the second stack structure including gate electrodes and interlayer insulating layers alternately stacked on each other in the first direction,
the first stack structure including a first lower gate electrode, first memory gate electrodes, and a first upper gate electrode sequentially stacked, and
the second stack structure including a second lower gate electrode, second memory gate electrodes, and a second upper gate electrode sequentially stacked; and
a channel structure including a plurality of channel portions penetrating the first stack structure and the second stack structure, respectively, the plurality of channel portions being connected to each other in the first direction,
wherein the channel structure includes
a filling insulating layer extending in the first direction within the plurality of channel portions;
a channel layer on a side surface of the filling insulating layer opposing the gate electrodes and the interlayer insulating layers; and
a channel dielectric layer including a tunneling layer, a charge storage layer, and a blocking layer, in order between the channel layer and the gate electrodes,
wherein the blocking layer includes a first region penetrating the first stack structure and a second region penetrating the second stack structure, and
wherein a first thickness of an upper portion of the blocking layer on a side surface of the charge storage layer in the first region is greater than a second thickness of a lower portion of the blocking layer on a side surface of the charge storage layer in the second region.

20. The data storage system of claim 19, wherein
in a channel portion of the plurality of channel portions on a lowermost end of the channel structure, the blocking layer includes a bent portion having a thickness that changes discontinuously between a vertical region in an extension direction of the channel portion on the lowermost end of the channel structure and a horizontal region extending in a second direction perpendicular to the first direction, and
a thickness of the vertical region is greater than a thickness of the horizontal region.
